(19) United States
(12) Patent Application Publication
(10) Pub. No.: US 2011/0057215 A1
(43) Pub. Date: Mar. 10, 2011

(54) Light-Emitting Diode Display Module

(76) Inventors: Shun-Chih Chen, Hsinchu (TW); Feng-Shih Chuang, Hsinchu (TW); Yu-Hung Hsiao, Hsinchu (TW); Kuo-Shu Huang, Hsinchu (TW)

(21) Appl. No.: 12/556,532

(22) Filed: Sep. 9, 2009

(51) Int. Cl. H01L 33/00

(52) U.S. Cl. 257/98; 257/E33.056

(57) ABSTRACT

An LED display module is provided, including a cover element, with the cover element having lenses on one side and the other side having a housing space to house a lighting module, a frame element and the water-proof pad located at the junction of the cover element and the frame element to prevent water from leaking through into the LED display module.

### FIELD OF THE INVENTION

The present invention generally relates to a structure for light-emitting diode (LED) display module, and more specifically to an LED display module with even light projection and good water-proof effect.

### BACKGROUND OF THE INVENTION

The large LED display is commonly used in different venues, such as stadium, sport arena, transportation stations and open plaza space. Through the internal computer control, the large LED display can broadcast sports events, live event images or commercial advertisements. This type of LED display is usually made of an array of a plurality of LED display modules connected and controlled by computer so that the display can show the images sent from the computer. Because this type of LED display is usually located outdoors, the water-proof effect is an important design consideration.

FIGS. 5 and 6 show a cross-sectional view and a side view of a conventional LED display module, respectively. As shown in FIGS. 5 & 6, conventional LED display module includes an upper cover A, a circuit substrate B, a light fixture C, and a water-proof pad D. Circuit substrate B includes a plurality of LEDs E. A layer of water-proof glue is applied to the contact surface between LEDs E and circuit substrate B. Upper cover A includes a plurality of frame holes A1. Frame holes A1 are for the LEDs to extend out, as shown in FIG. 6. Circuit substrate B is fixed between upper cover A and fixture C so that the surface of circuit substrate B having LEDs E is water-proof. Light fixture C is a large frame fixture, and is engaged to the main base of the display when assembled. Water-proof pad D is located at the back of light fixture C for preventing water from leaking through after light fixture C and the aforementioned main base of the display are assembled. It is clear that the water-proof effect of the LED display module is accomplished by the tight locking between the elements. Therefore, the relative position and the locking between the elements will greatly affect the water-proof effect.

A large-sized LED display usually includes a plurality of LEDs deployed on a circuit substrate. In addition, in the aforementioned LED display module, a plurality of engaging columns A2 are formed on the bottom of upper cover A, and a plurality of engaging bases C1 are formed on light fixture C so that with the engagement of engaging columns A2 and engaging bases C1, circuit substrate B is sandwiched between upper cover A and light fixture C. However, for a large-sized LED display, the area of the circuit substrate will also be very large. With the aforementioned structure, if the point to point engagement is applied to the corners of the circuit substrate to fasten the circuit substrate, a bend may occur because the circuit substrate of each engagement structure is not aligned, which will result in the light projection direction of the LEDs on the circuit substrate and the light projected from the upper cover will not be uniform.

### SUMMARY OF THE INVENTION

The present invention has been made to overcome the aforementioned drawback of conventional LED display module. The primary object of the present invention is to provide a design with good water-proof effect and constructing elements easy to assemble.

To achieve the aforementioned objects, the present invention provides an LED display module, including a cover element, a lighting module, a frame element, a water-proof pad and at least an enhancing rib. One side of the cover element includes a plurality of lens, and the other side of the cover element is a housing space. The lighting module is located inside the housing space of the cover element, and includes at least an LED and a circuit substrate. The frame element is located inside the housing space to sandwich the circuit substrate between the cover element and the frame element. The water-proof pad is ring-shaped and is located at the junction of the frame element and the cover element.

In comparison with the design of the conventional LED display module, the present invention uses a monolithic cover element to cover the lighting module. Unlike the upper cover and the lower cover of the conventional design, the monolithic cover element of the present invention provides better water-proof effect. On the other hand, the present invention include the cover element and the water-proof pad to prevent rain from leaking through, therefore, no additional water-proof glue is required and the manufacturing process is simplified.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

The present invention can be understood in more detail by reading the subsequent detailed description in conjunction with the examples and references made to the accompanying drawings, wherein:

FIG. 1 shows a front exploded view of the LED display module according to the present invention;

FIG. 2 shows a back exploded view of the LED display module according to the present invention;

FIG. 3 shows a cross-sectional view of the LED display module according to the present invention;

FIG. 4A shows a schematic view of the present invention in actual application;

FIG. 4B shows a top view of the LED display module according to the present invention;

FIG. 5 shows a schematic cross-section view of a conventional LED display module; and

FIG. 6 shows a side view of a conventional LED display module.

### DETAILED DESCRIPTION OF THE PREFERRED EMBODIMENTS

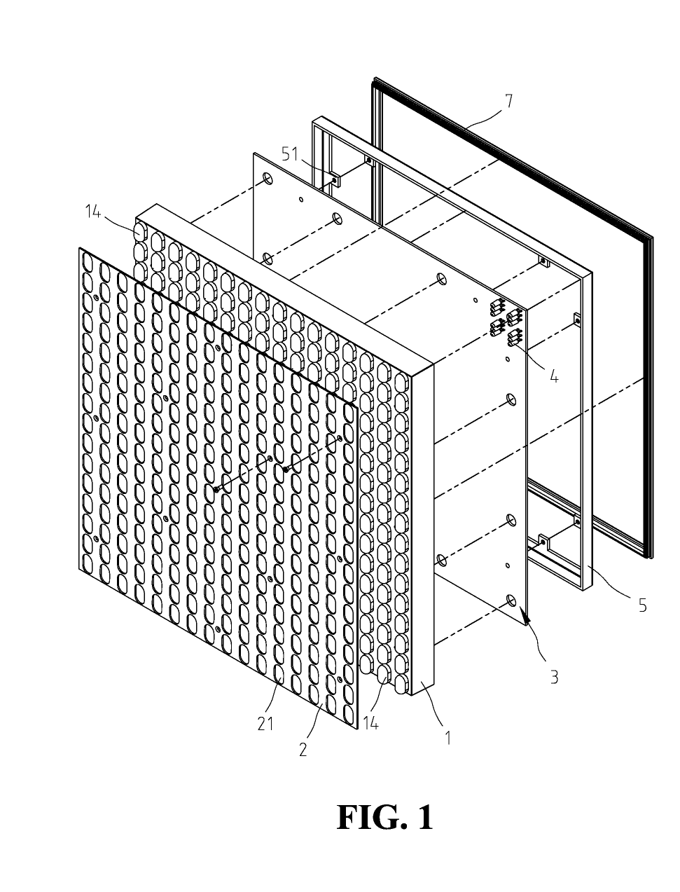

FIGS. 1 & 2 show the front exploded view and the back exploded view of the embodiment of the present invention, respectively. The LED display module of the present invention includes a cover element 1, a shade 2, a lighting module 3, a frame element 5, at least an enhancing rib 6 and a water-proof pad 7. Cover element 1 is monolithic and can be made of plastic or acrylic. Cover element 1 includes a housing space 11. The bottom of housing space 11 forms a plurality of substrate engaging columns 12 and frame engaging columns 13. In particular, the surfaces of substrate engaging columns 12 include plural side wings 121 along the column direction. The surface of cover element 1 opposite to housing space 11 includes plural rows of convex lenses 14. Lenses 14 are transparent with shape matching the light projection angle of the LEDs. The convex space of lenses 14 can accommodate the corresponding LEDs. Shade 2 is an opaque plate formed by plastic or acrylic. Shade 2 includes plural rows of limiting holes 21 with positions matching the positions of lenses 14 of cover element 1. Lighting module 3 includes a circuit substrate 31 fitting into housing space 11 of cover element 1. One side of circuit substrate 31 is coupled with plural rows of LEDs 4 (partially shown in the figures). The arrangement of LEDs 4 matches the arrangement of lenses 14. Plural substrate engaging holes 311 are drilled on circuit substrate 31 with positions matching substrate engaging columns 12 of cover element 1. Frame element 5 can be made of metal or other rigid material, with a size fitting into housing space 11 of cover element 1. Each frame side extends plural fastening plates 51 horizontally and inwardly. Plural frame engaging holes 511 are drilled on fastening plates 51 with positions matching frame engaging columns 13 of cover element 1. Water-proof pad 7 can be a ring made of plastic to match the shape of cover element 1. The size of water-proof pad 7 is between the size of frame element 5 and the size of cover element 1.

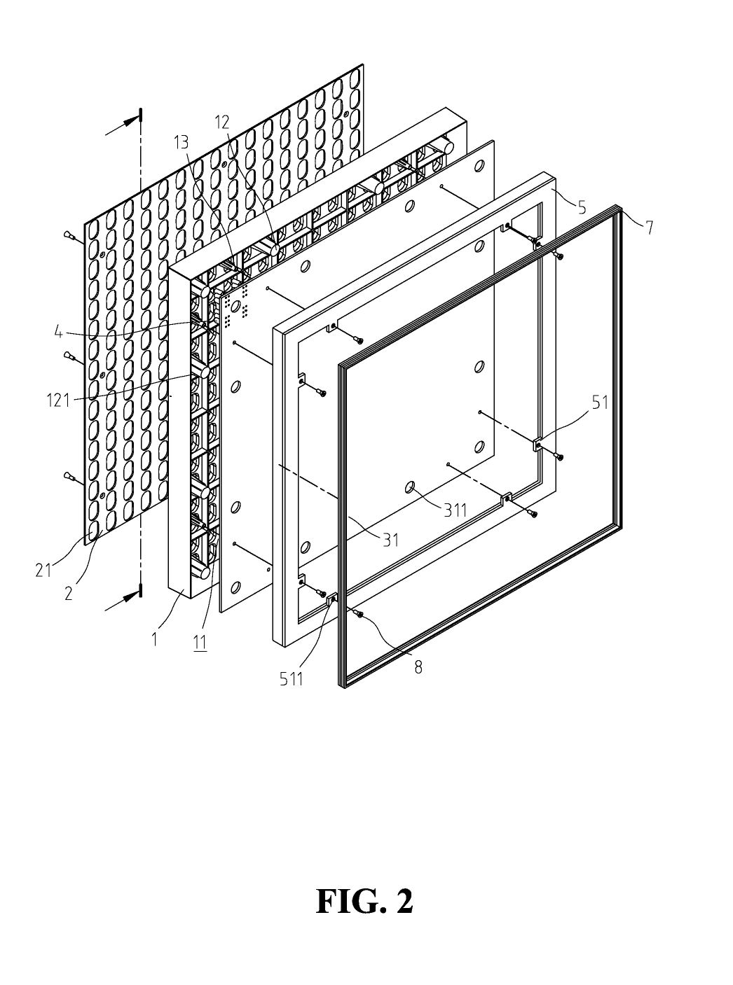

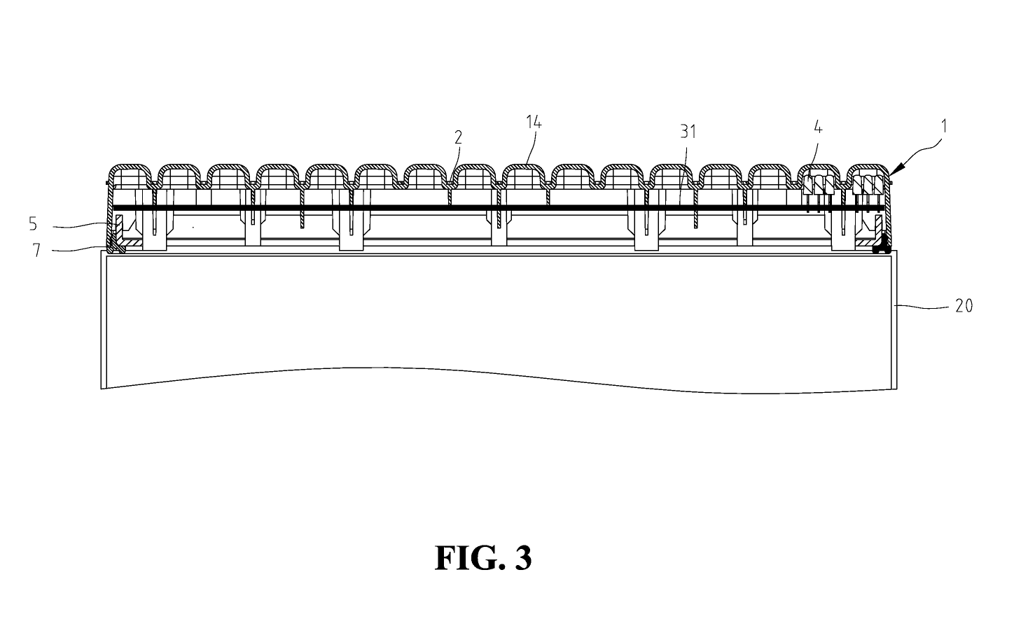

Refer to FIGS. 1, 2 & 3, where FIG. 3 shows a cross-section view of the LED display module of the present invention. The way to assemble is to match limiting holes 21 of shade 2 with lenses 14 on the surface of cover element 1 so that shade 2 falls on the surface of cover element 1. Plural screws 8 are used to lock shade 2 to the surface of cover element 1. Substrate engaging holes 311 are matched with substrate engaging columns 12 inside housing space 11 of cover element 1, and circuit substrate 31 is placed inside housing space 11 so that substrate engaging columns 12 pass through substrate engaging holes 311 until the surface of circuit substrate 31 touches side wings 121 of substrate engaging columns 12. After the surface of circuit substrate 31 touches side wings 121 of substrate engaging columns 12, circuit substrate 31 is supported uniformly by side wings 121 of substrate engaging columns 12, and LEDs 4 can be accommodated inside the concave space of convex lenses 14. LEDs 4 of the present embodiment are arranged in a manner of groups of three LEDs 4, placed inside the concave space of convex lenses 14. Then, frame engaging holes 511 on fastening plates 5 of frame element 5 are matched with frame engaging columns 13. With frame engaging columns 13 supporting frame element 5, plural screws 8 are used to lock frame engaging holes 511 and frame engaging columns 13 so that frame element 5 is engaged to cover element 1, with frame element 5 inside housing space 11 and circuit substrate 31 sandwiched between cover element 1 and frame element 5. Frame element 5 is for increasing the strength of the entire module. In the mean time, the junction of frame element 5 and cover element 1 has a ring gap for tightly embedding water-proof pad 7.

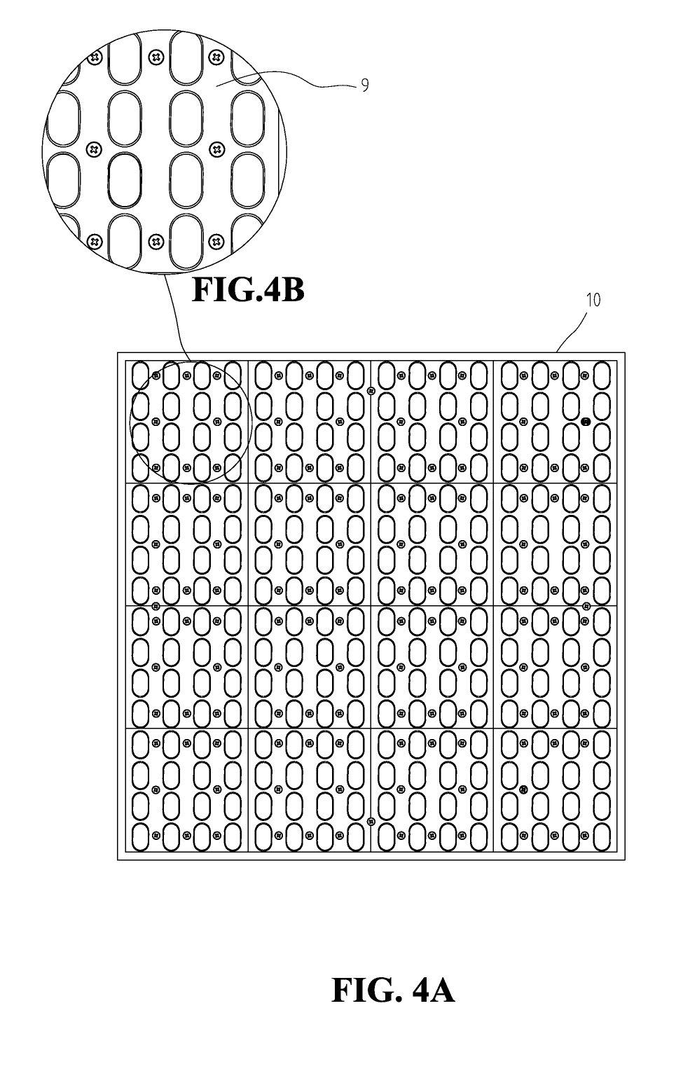

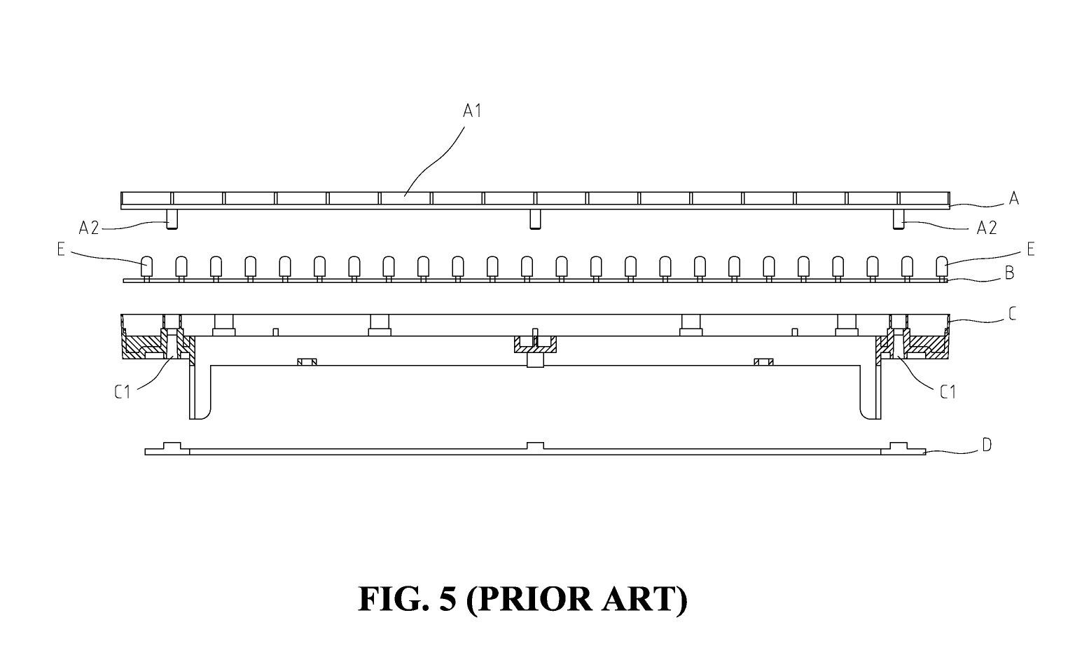

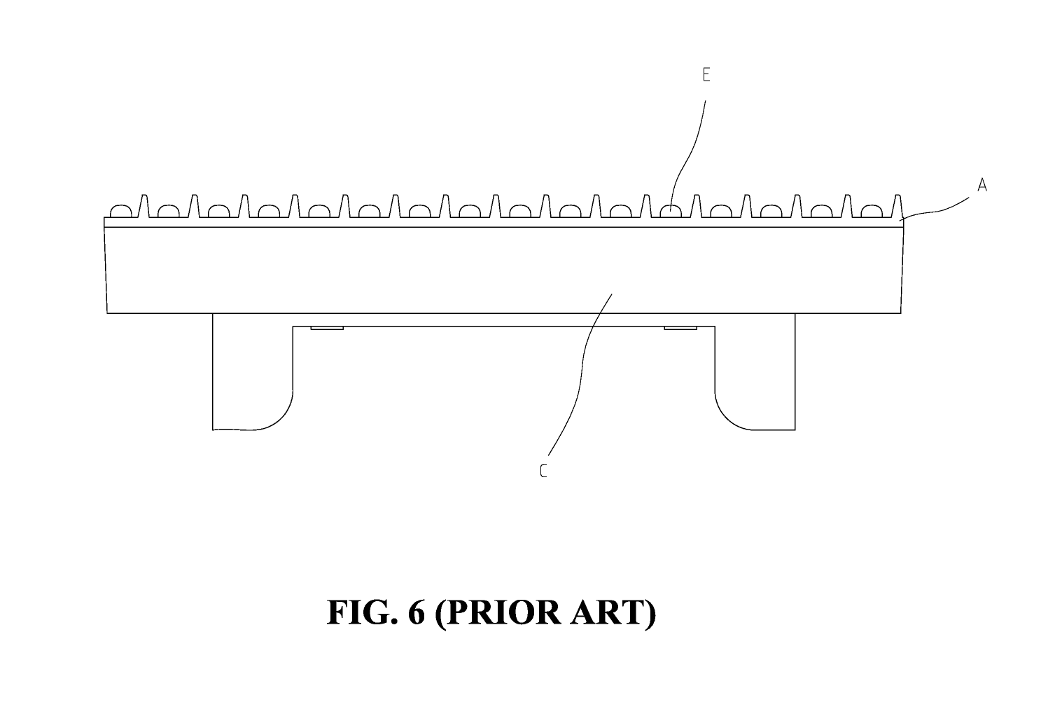

FIG. 4A shows a schematic view of the present invention in actual application. A plurality of LED display modules 9 of the present invention can be assembled to form a large-sized display 10. FIG. 4B shows a single LED display module 9. Refer to FIG. 3. The LED display module of the present invention can be engaged to main base 20 or other objects. Because a water-proof pad 7 is included between cover element 1 and frame element 5, the water will not leak through to the module and main base 20. Hence, the present invention is suitable to outdoor applications.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. An LED display module, comprising:
a cover element, having a housing space, surface of said cover element having a plurality of lenses;
a lighting module, located inside said housing space, comprising at least an LED and a circuit substrate;
a frame element, located inside said housing space, sand sandwiching said circuit substrate between said cover element and said frame element; and
a water-proof pad, having a ring shape, located at junction of said frame element and said cover element.

2. The LED display module as claimed in claim 1, wherein said cover element further comprises a shade located on the surface of said cover element, and said shade has a plurality of limiting holes with positions matching said lenses of said cover element.
